(19) United States
(12) Patent Application Publication
(10) Pub. No.: US 2006/0219663 A1
(43) Pub. Date: Oct. 5, 2006

(54) Metal CMP process on one or more polishing stations using slurries with oxidizers

(75) Inventors: Shi-Ping Wang, Fremont, CA (US); Martin S. Wohlert, San Jose, CA (US); Alain Duboust, Sunnyvale, CA (US); Renhe Jia, Berkeley, CA (US); Feng Q. Liu, San Jose, CA (US); Yuan A. Tian, San Jose, CA (US); Liang-Yuh Chen, Foster City, CA (US); Stan D. Tsai, Fremont, CA (US); Wei-Yung Hsu, Santa Clara, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/338,146

(22) Filed: Jan. 23, 2006

Related U.S. Application Data
(60) Provisional application No. 60/666,865, filed on Mar. 31, 2005.

(51) Int. Cl. C03C 15/00; H01L 21/302; B44C 1/22; H01L 21/461

(52) U.S. Cl. 216/88; 438/692; 438/734

(57) ABSTRACT

Polishing compositions and methods for removing conductive materials and barrier materials from a substrate surface are provided. In one aspect, a full sequence electrochemical mechanical planarization technique is provided. In another aspect, a hybrid planarization technique using combination of at least one chemical mechanical polishing process and at least one electrochemical mechanical polishing process is provided. In addition, a multi-step polishing process for polishing a substrate surface using at least two oxidizers in one or more polishing composition is described. The polishing composition may be used in the full sequence or the hybrid planarization technique. The polishing compositions and methods described herein improve the effective removal rate of materials from the substrate surface with a reduction in planarization defects.

### CROSS-REFERENCE TO RELATED APPLICATIONS

This application claims benefit of U.S. provisional patent application Ser. No. 60/666,865, filed Mar. 31, 2005, which is herein incorporated by reference.

### BACKGROUND OF THE INVENTION

Reliably producing sub-half micron and smaller features is one of the key technologies for the next generation of very large scale integration (VLSI) and ultra large-scale integration (ULSI) of semiconductor devices. However, as the limits of circuit technology are pushed, the shrinking dimensions of interconnects in VLSI and ULSI technology have placed additional demands on processing capabilities. Reliable formation of interconnects is important to VLSI and ULSI success and to the continued effort to increase circuit density and quality of individual substrates and die.

Multilevel interconnects are formed using sequential material deposition and material removal techniques on a substrate surface to form features therein. As layers of materials are sequentially deposited and removed, the uppermost surface of the substrate may become non-planar across its surface and require planarization prior to further processing. Planarization or “polishing” is a process in which material is removed from the surface of the substrate to form a generally even, planar surface by applying a mechanical force on to the substrate surface and also performing chemical abrasion from a polishing slurry. Planarization is useful in removing excess deposited material and undesired surface topography to provide an even surface for subsequent photolithography and other semiconductor manufacturing processes.

It is difficult to planarize a metal surface of a damascene inlay to a high degree of surface planarity. As shown in FIGS. 1A and 1B, a damascene inlay formation process may include etching feature definitions 11 in a dielectric material 10, such as a silicon oxide layer, on a substrate surface, depositing a barrier layer 13 in the feature definitions 11, and depositing a thick layer of a metal material 12 on the barrier layer 13. The metal material 12 is chemical mechanically polished (CMP) to expose the barrier layer 13 between the feature definitions 11. Next, the barrier layer 13 is then chemical mechanically polished to remove the barrier layer to expose portions of the dielectric material 10 between the feature definitions 11 as shown in FIG. 1A. Chemical mechanical polishing techniques to planarize the layer of the metal material 12 and the barrier layer 13 often results in topographical defects, such as dishing and erosion, that may affect subsequent processing of the substrate.

Dishing occurs when a portion of the surface of the inlaid metal of the interconnection formed in the feature definitions in the interlayer dielectric is excessively polished, resulting in one or more concave depressions, which may be referred to as concavities or recesses. Referring to FIG. 1A, subsequent to planarization of a metal material 12 and the barrier layer 13, a portion of the metal material 12 may be depressed by an amount D, referred to as the amount of dishing. Dishing is more likely to occur in wider or less dense features on a substrate surface.

Conventional planarization techniques also sometimes result in erosion, characterized by excessive polishing of the layer not targeted for removal, such as a dielectric material surrounding a metal filled feature definition, such as metal interconnect structures, copper lines, tungsten plugs or vias. Referring to FIG. 1B, a metal material 21 and a barrier layer 23 formed in a dense array of feature definitions 22 are inlaid in a dielectric material 20. Polishing the substrate may result in loss, or erosion E, of the dielectric material 20 between the metal filled feature definitions. Erosion is observed to occur near narrower or more dense features formed in the substrate surface.

Electrochemical mechanical planarization (ECMP) is a technique used to remove conductive materials from a substrate surface by electrochemical dissolution while concurrently polishing the substrate with reduced mechanical abrasion compared to conventional planarization processes. Electrochemical dissolution is performed by applying a bias between a cathode and a substrate surface to remove conductive materials from the substrate surface into a surrounding electrolyte. Typically, the bias is applied to the substrate surface by a conductive polishing material on which the substrate is processed. A mechanical component of the polishing process is performed by providing a low down force, low polishing pressure as compared to conventional CMP, and relative motion between the substrate and the conductive polishing material that enhances the removal of the conductive material from the substrate. ECMP systems may generally be adapted for deposition of conductive materials on the substrate by reversing the polarity of the bias.

As discussed above, one challenge associated conventional CMP or ECMP for polishing metal material is that after a large portion of a bulk metal material layer has been removed, the remaining metal material is hard to polish without the problems associated with dishing and erosion. It is especially difficult to remove the residual metal material without damage to an underlying barrier layer or dielectric layers.

In addition, most CMP slurries or ECMP electrolytes requires an oxidizer to remove a metal material form a substrate surface. While some oxidizers provide good material removal rate and good planarization efficiency (low dishing and low erosion), they tend to leave residues with poor defect performance, leaving behind surface defects, such as surface roughness, agglomerated materials, crystal lattice damage, micro scratches, and contaminated layers or materials after polishing.

Therefore, there is a need for a polishing technique which provides improved compositions, methods, and polishing systems for removing conductive metal and/or barrier materials from a substrate and minimizes dishing, erosion, and the formation of topographical and surface defects to the substrate.

### SUMMARY OF THE INVENTION

Aspects of the invention provide compositions, methods, and planarization systems for removing conductive materials by a polishing technique. In one aspect, a method for removing at least a metal material from a surface of the substrate includes disposing the substrate on a planarization station, applying a first polishing composition having a persulfate oxidizer to the surface of the substrate to remove at least a portion of the metal material and polishing the substrate at a first removal rate. The method further includes applying a second polishing composition having a peroxide oxidizer to the surface of the substrate to remove a residual portion of the metal material and polishing the substrate at a second removal rate.

In another aspect, a method is provided for removing at least a metal material from a surface of the substrate, including disposing the substrate on an electrochemical mechanical planarization station and polishing the substrate by a full sequence planarization technique. The full sequence planarization includes applying a first polishing composition having a first persulfate oxidizer to the surface of the substrate to remove at least a portion of the metal material, polishing the substrate at a first removal rate, applying a second polishing composition having a second oxidizer to the surface of the substrate to remove a residual portion of the metal material, and polishing the substrate at a second removal rate.

In still another aspect, a method for removing at least a metal material from a surface of the substrate includes polishing the substrate by a hybrid planarization technique. The hybrid planarization includes disposing the substrate on a first planarization station, applying a first polishing composition having a first oxidizer to the surface of the substrate to remove at least a portion of the metal material, polishing the substrate at a first removal rate, transferring the substrate to a second planarization station, applying a second polishing composition having a second oxidizer to the surface of the substrate to remove a residual portion of the metal material, and polishing the substrate at a second removal rate.

In still another aspect, a method is provided for removing at least a metal material from a surface of the substrate, including polishing the substrate by a hybrid planarization technique. The hybrid planarization technique includes disposing the substrate on a chemical mechanical planarization station, applying a first polishing composition to the surface of the substrate to remove at least a portion of the metal material, polishing the substrate at a first removal rate until a first end point is detected by an end point detection module connected to the chemical mechanical planarization station, transferring the substrate to an electrochemical mechanical planarization station, applying a second polishing composition to the surface of the substrate to remove a residual portion of the metal material, and polishing the substrate at a second removal rate until the surface of the substrate is planarized.

In a further aspect, a method for removing at least a metal material from a surface of the substrate includes disposing the substrate on a planarization station, applying a first polishing composition comprising ammonium persulfate to the surface of the substrate to remove at least a portion of the metal material, polishing the substrate at a first removal rate, applying a second polishing composition comprising hydrogen peroxide to the surface of the substrate to remove a residual portion of the metal material, and polishing the substrate at a second removal rate.

### BRIEF DESCRIPTION OF THE DRAWINGS

So that the manner in which the above recited aspects of the present invention are attained and can be understood in detail, a more particular description of embodiments of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIGS. 1A and 1B schematically illustrate the prior art phenomenon of dishing and erosion respectively.

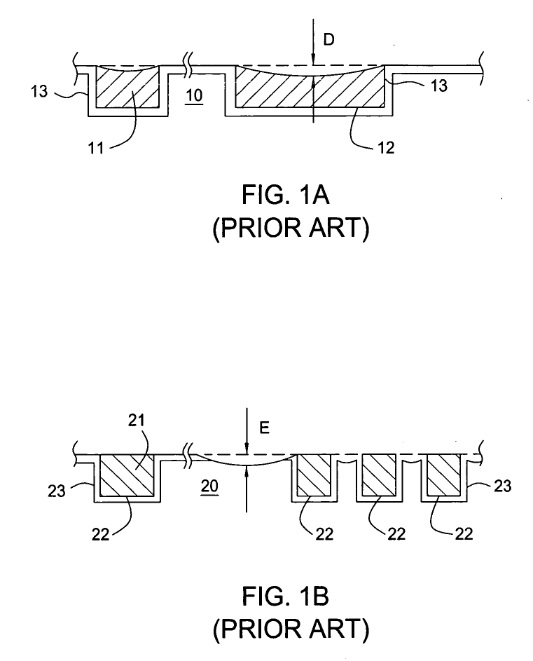

FIG. 2 is a plan view of a planarization system.

FIG. 3 is a sectional view of one embodiment of an electrochemical mechanical polishing (ECMP) station of the planarization system of FIG. 2

FIG. 4 is a vertical sectional view of another embodiment of an ECMP station.

FIG. 5 is a schematic illustration of a polishing process according to one embodiment of the invention.

### DETAILED DESCRIPTION

In general, aspects of the invention provide compositions and methods for removing at least a metal material from a substrate surface. The invention is described below in reference to a planarization process by an electrochemical mechanical planarization (ECMP) technique. However, aspects of the invention can also be applied to a chemical mechanical planarization (CMP) technique.

The words and phrases used herein should be given their ordinary and customary meaning in the art by one skilled in the art unless otherwise further defined. Chemical polishing should be broadly construed and includes, but is not limited to, planarizing a substrate surface using chemical activity. Electropolishing should be broadly construed and includes, but is not limited to, planarizing a substrate by the application of electrochemical activity. Electrochemical mechanical planarization (ECMP) should be broadly construed and includes planarizing a substrate by the application of electrochemical activity, mechanical activity, and chemical activity to remove material from a substrate surface.

Polishing composition should be broadly construed and includes, but is not limited to, a composition that provides chemical activity to remove materials from a substrate surface in a liquid medium, which generally comprises materials known as slurries for conventional CMP, electrolytes for ECMP, and other chemical components. The amount of each chemical component in a polishing composition can be measured in volume percent or weight percent. Volume percent refers to a percentage based on volume of a desired liquid component divided by the total volume of all of the liquid in a complete working solution. A percentage based on weight percent is the weight of the desired component divided by the total weight of all of the liquid components in a complete working solution.

Apparatus

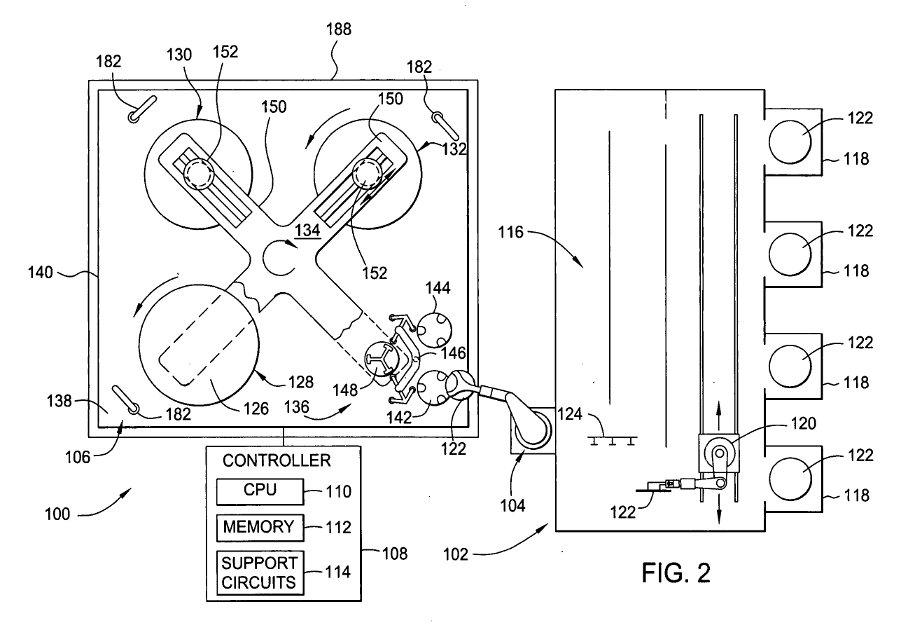

FIG. 2 is a plan view of one embodiment of a planarization system 100 having an apparatus for electrochemically processing a substrate. The planarization system 100 generally comprises a factory interface 102, a loading robot 104, and a planarization module 106. The loading robot 104 is disposed proximate the factory interface 102 and the planarization module 106 to facilitate the transfer of one or more substrates 122 therebetween.

A controller 108 is provided to facilitate control and integration of the modules of the planarization system 100. The controller 108 comprises a central processing unit (CPU) 110, a memory 112, and support circuits 114. The controller 108 is coupled to the various components of the planarization system 100 to facilitate control of, for example, the planarizing, cleaning, and transfer processes.

The factory interface 102 generally includes a cleaning module 116 and one or more wafer cassettes 118. An interface robot 120 is employed to transfer substrates 122 between the wafer cassettes 118, the cleaning module 116 and an input module 124. The input module 124 is positioned to facilitate transfer of substrates 122 between the planarization module 106 and the factory interface 102 by grippers, for example vacuum grippers or mechanical clamps (not shown).

The planarization module 106 includes at least a first planarization station 128, a second planarization station 130, and a third planarization station 132 disposed in an environmentally controlled enclosure 188. Each of the three planarization stations may be adapted to be a chemical mechanical planarization (CMP) station or an electrochemical mechanical planarization (ECMP) station.

In one embodiment of the invention, the planarization module 106 includes three ECMP planarization stations provided for a full sequence ECMP technique to polish various conductive metal and barrier materials. For example, a first ECMP station may be provided for bulk conductive metal material removal through a first electrochemical mechanical process, a second ECMP station may be provided for residual metal material removal through a second electrochemical mechanical process, and a third ECMP station is provided for barrier layer material removal through a third electrochemical mechanical process. It is also contemplated that more than one electrochemical mechanical process can be performed in each of the first, second, and third ECMP stations in the planarization module 106.

Conductive metal materials that can benefit from embodiments of the invention include, but are not limited to, copper, tungsten, and their alloys and combinations thereof. Tungsten material includes tungsten, tungsten nitride, and tungsten silicon nitride, among others. The invention contemplates the removal of other metal materials including aluminum, platinum, cobalt, gold, silver, ruthenium and combinations thereof. Barrier layer materials of the invention include, but are not limited to, titanium (Ti), titanium nitride, titanium silicon nitride, tantalum (Ta), tantalum nitride, tantalum silicon nitride, ruthenium (Ru), and combinations thereof.

As an example, a conductive metal material, such as copper, tungsten, or its alloy, in a metal layer of an interconnect structure can be removed by polishing in a first ECMP station and cleaning the residual copper or tungsten material by polishing in a second ECMP station. The underlying barrier material, such as tantalum, tantalum nitride, titanium, titanium nitride, or its alloy thereof, can be polished by a third ECMP station.

In another embodiment of the invention, the planarization module 106 includes one or more ECMP stations and one or more CMP stations provided for a hybrid polishing technique to polish various conductive metal and barrier materials. For example, a first ECMP station may be provided for bulk conductive metal material removal through a first electrochemical mechanical polishing process, a second conventional CMP station may be provided for residual metal material removal through a second chemical mechanical polishing process, and a third conventional CMP station or ECMP station maybe provided for barrier layer material removal through a third chemical mechanical or electrochemical mechanical polishing process. As an example, a conductive metal material, such as copper or its alloy, in a metal layer of an interconnect structure can be removed by polishing in a first ECMP station with a low polish pressure and overpolished or cleared by polishing in a second conventional CMP station. An underlying tantalum or tantalum nitride barrier material can be polished by a third ECMP or conventional CMP station.

It is also contemplated that more than one electrochemical mechanical process or more than one chemical mechanical polishing process can be performed in each of the first, second, and third stations in the planarization module 106. For example, a conductive metal material, such as copper or its alloy, in a metal layer of an interconnect structure can be removed by polishing in a first ECMP station with a low polish pressure and overpolished or cleared by polishing in the same first ECMP station. An underlying tantalum or tantalum nitride barrier material can be polished by a second conventional CMP station.

In still another embodiment of the invention, a hybrid polishing technique to polish various conductive metal and barrier materials is provided such that the planarization module 106 includes a first conventional CMP station for bulk conductive metal material removal through a first chemical mechanical polishing process, a second ECMP station for residual metal material removal through a second electrochemical mechanical polishing process, and a third conventional CMP station for barrier layer material removal through a third chemical mechanical polishing process. In this instance, the substrates which have conductive metal material deposited thereon to be planarized may not have much incoming topography such that the first polishing station needs not to require a low polishing pressure and thus may not need to be an ECMP station. It is contemplated that the first conventional CMP process may provide bulk conductive metal material removal with high removal rate and good surface finish and the second ECMP process, which includes a lower polishing pressure than a conventional CMP process, may provide final clearing of the residual conductive metal material removal. The residual metal material may be difficult to clear using a conventional CMP process without a problem with oxide erosion; thus, the invention provides a second electrochemical mechanical polishing process on a second ECMP station for residual metal material removal such that there is no problem with dishing and oxide erosion due to the low mechanical forces and little or low abrasive particles used in the second electrochemical mechanical polishing process.

For example, a conductive metal material, such as tungsten or its alloy, in a feature definitions, such as tungsten plugs or vias, of an interconnect structure may have very dense arrays of these features and a large field oxide region with little or low topography variation, such that the bulk of the tungsten material layer can be quickly removed by polishing in a first CMP station using regular polishing pressure and high removal rate and monitored by an endpoint detection module. Then, to avoid the problem with dishing and erosion in the very dense patterned arrays or features, the remaining tungsten can be cleared or overpolished by polishing in a second ECMP station using a polishing pressure of about 2 psi or less and an ECMP electrolyte. The underlying titanium or titanium nitride barrier material can be polished by an third ECMP or conventional CMP station.

Examples of planarization modules that can be adapted to benefit from the invention include MIRRA® Chemical Mechanical Planarizing Systems, MIRRA MESA™ Chemical Mechanical Planarizing Systems, REFLEXION® Chemical Mechanical Planarizing Systems, REFLEXION® LK Chemical Mechanical Planarizing Systems, and REFLEXION LK ECMP™ Chemical Mechanical Planarizing Systems, all available from Applied Materials, Inc. of Santa Clara, Calif. Other planarization modules, including those that use processing pads, planarizing webs, or a combination thereof, and those that move a substrate relative to a planarizing surface in a rotational, linear, orbital, or other motions may also be adapted to benefit from the invention.

It is contemplated that more than one polishing station may be utilized to perform a multi-step removal process. Alternatively, each of the first, second, and third planarization stations 128, 130, 132 may be utilized to perform both the bulk, the residual, and/or multi-step material removal on a single station. Examples of a ,ulti-step removal process that can be adapted to benefit from the invention co-pending U.S. patent application Ser. No. 10/941,060, entitled “Full Sequence Metal and Barrier Layer Electrochemical Mechanical Processing”, filed on Sep. 14, 2004, which is herein incorporated by reference in its entirety.

As shown in FIG. 2, the planarization module 106 also includes a transfer station 136 and a carousel 134 that are disposed on an upper or first side 138 of a machine base 140. The transfer station 136 includes an input buffer station 142, an output buffer station 144, a transfer robot 146, and a load cup assembly 148. The input buffer station 142 receives substrates 122 from the factory interface 102 by means of the loading robot 104. The loading robot 104 is also utilized to return polished substrates 122 from the output buffer station 144 to the factory interface 102. The transfer robot 146 is utilized to move substrates 122 between the input buffer station 142, the output buffer station 144 and the load cup assembly 148.

The transfer robot 146 includes two gripper assemblies (not shown), each having pneumatic gripper fingers that hold the substrate by the substrate's edge. The transfer robot 146 may simultaneously transfer a substrate to be processed from the input buffer station 142 to the load cup assembly 148 while transferring a processed substrate from the load cup assembly 148 to the output buffer station 144. An example of a transfer station that may be used to advantage is described in U.S. Pat. No. 6,156,124, issued Dec. 5, 2000 to Tobin, which is herein incorporated by reference in its entirety.

The carousel 134 is centrally disposed on the base 140. The carousel 134 typically includes a plurality of arms 150, each supporting a planarization head assembly 152. Two of the arms 150 depicted in FIG. 2 are shown in phantom such that the transfer station 136 and a planarization surface 126 of the first planarization station 128 may be seen. The carousel 134 is indexable such that one or more planarization head assemblies 152 may be moved between the planarization stations 128, 130, 132 and the transfer station 136. One carousel that may be utilized to advantage is described in U.S. Pat. No. 5,804,507, issued Sep. 8, 1998 to Perlov, et al, which is hereby incorporated by reference in its entirety.

A conditioning device 182 is disposed on the base 140 adjacent each of the planarization stations 128, 130, 132. The conditioning device 182 include a diamond disk which may periodically pressed against a polishing pad or related planarization articles/pad assemblies disposed in the planarization stations 128, 130, 132 and condition the polishing pad for uniform planarization results between substrates.

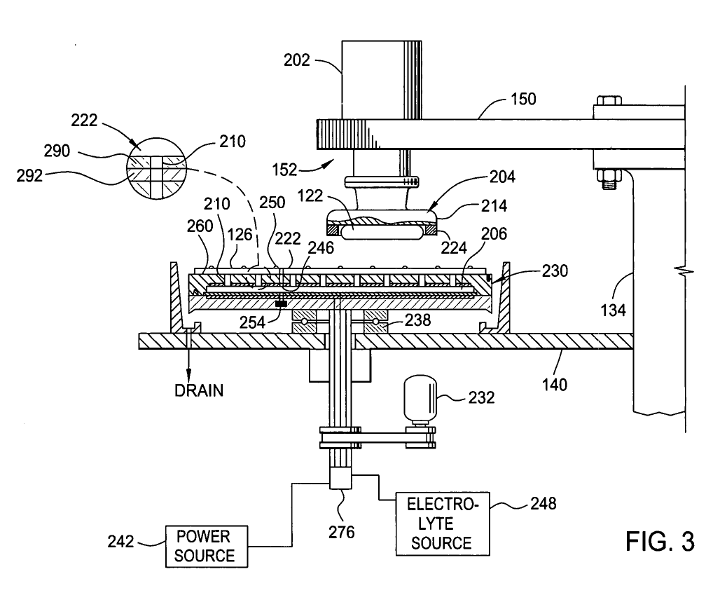

FIG. 3 depicts a sectional view of one of the planarization head assemblies 152 positioned over one embodiment of the first, second, or third planarization station. The planarization head assembly 152 generally comprises a drive system 202 coupled to a planarization head 204. The drive system 202 generally provides at least rotational motion or other motion to the planarization head 204. The planarization head 204 additionally may be actuated toward the planarization station such that the substrate 122 retained in the planarization head 204 may be disposed against the planarization surface 126 of the planarization station during processing. The drive system 202 is coupled to the controller 108 which can provide a signal to the drive system 202 for controlling the rotational speed and direction of the planarization head 204.

For example, the planarization head may be a TITAN HEAD™, TITAN PROFILER™, or TITAN CONTOUR™ wafer carrier manufactured by Applied Materials, Inc. Generally, the planarization head 204 comprises a housing 214 and a retaining ring 224 that defines a center recess in which the substrate 122 is retained. The retaining ring 224 circumscribes the substrate 122 disposed within the planarization head 204 to prevent the substrate from slipping out from under the planarization head 204 while processing. The retaining ring 224 can be made of plastic materials such as polyphenylene sulfide (PPS), polyetheretherketone (PEEK), and the like, or conductive materials such as stainless steel, Cu, Au, Pd, and the like, or some combination thereof. It is further contemplated that a conductive retaining ring 224 may be electrically biased to control the electric field during ECMP. Conductive or biased retaining rings tend to slow the polishing rate proximate the edge of the substrate. It is contemplated that other planarization heads may be utilized.

The planarization station generally includes a platen assembly 230 that is rotationally disposed on the base 140. The platen assembly 230 is supported above the base 140 by a bearing 238 so that the platen assembly 230 may be rotated relative to the base 140. An area of the base 140 circumscribed by the bearing 238 is open and provides a conduit for the electrical, mechanical, pneumatic, control signals and connections communicating with the platen assembly 230.

Conventional bearings, rotary unions and slip rings, collectively referred to as a rotary coupler 276, are provided such that electrical, mechanical, fluid, pneumatic, control signals and connections may be coupled between the base 140 and the rotating platen assembly 230. The platen assembly 230 is typically coupled to a motor 232 that provides the rotational motion to the platen assembly 230. The motor 232 is coupled to the controller 108 that provides a signal for controlling for the rotational speed and direction of the platen assembly 230.

A top surface 260 of the platen assembly 230 supports a processing pad assembly 222 thereon. The processing pad assembly may be retained to the platen assembly 230 by magnetic attraction, vacuum, clamps, adhesives and the like.

A plenum 206 is defined in the platen assembly 230 to facilitate uniform distribution of an electrolyte solution to the planarization surface 126. A plurality of passages are formed in the platen assembly 230 to allow the electrolyte solution, provided to the plenum 206 from an electrolyte source 248, to flow uniformly though the platen assembly 230 and into contact with the substrate 122 during processing. One aspect of the invention provides one or more polishing compositions that can be used as different electrolyte compositions to be provided to the plenum 206 of the platen assembly 230 during different stages of substrate processing.

The processing pad assembly 222 includes an electrode 292 and at least a planarization portion 290. The electrode 292 is typically comprised of a conductive material, such as stainless steel, copper, aluminum, gold, silver and tungsten, among others. The electrode 292 may be solid, impermeable to electrolyte, permeable to electrolyte or perforated. At least one contact assembly 250 extends above the processing pad assembly 222 and is adapted to electrically couple the substrate 122 being processed on the processing pad assembly 222 to a power source 242 so that the substrate 122 may be biased relative to the electrode 292 during processing. The electrode 292 is also coupled to the power source 242 so that an electrical potential may be established between the substrate 122 and the electrode 292.

A meter (not shown) is provided to detect a metric indicative of the electrochemical process. The meter may be coupled or positioned between the power source 242 and at least one of the electrode 292 or the contact assembly 250. The meter may also be integral to the power source 242. In one embodiment, the meter is configured to provide the controller 108 with a metric indicative of processing, such a current and/or voltage. This metric may be utilized by the controller 108 to adjust the processing parameters in-situ or to facilitate endpoint or other process stage detection.

A window 246 is provided through the processing pad assembly 222 and/or the platen assembly 230, and is configured to allow a sensor 254, positioned below the processing pad assembly 222, to sense a metric indicative of polishing performance. For example, the sensor 254 may be an eddy current sensor or an interferometer, among other sensors. The metric, provided by the sensor 254 to the controller 108, provides information that may be utilized for processing profile adjustment in-situ, endpoint detection, or detection of another point during an electrochemical polishing process. In one embodiment, the sensor 254 is an interferometer capable of generating a collimated light beam, which during processing, is directed at and impinges on a side of the substrate 122 that is being polished. The interference between reflected signals is indicative of the thickness of the conductive layer of material being processed. One sensor that may be utilized to advantage is described in U.S. Pat. No. 5,893,796, issued Apr. 13, 1999, to Birang, et al., which is hereby incorporated by reference in its entirety.

The processing pad assembly 222 suitable for removal of conductive material from the substrate 122 may generally include a planarization surface 126 that is substantially dielectric. Other embodiments of the processing pad assembly 222 suitable for removal of conductive material from the substrate 122 may generally include a planarization surface 126 that is substantially conductive. Apertures 210, formed through the planarization portion 290 and the electrode 292 and the any elements disposed below the electrode 292, allow the electrolyte solution to establish a conductive path between the substrate 122 and the electrode 292.

For example, the planarization portion 290 of the processing pad assembly 222 is a dielectric, such as polyurethane. Examples of processing pad assemblies that may be adapted to benefit from the invention are described in U.S. patent application Ser. No. 10/455,941, filed Jun. 6, 2003, entitled “Conductive Planarizing Article For Electrochemical Mechanical Planarizing”, and U.S. patent application Ser. No. 10/455,895, filed Jun. 6, 2003, entitled “Conductive Planarizing Article For Electrochemical Mechanical Planarizing,” both of which are hereby incorporated by reference in their entireties.

The contact assemblies 250 are generally electrically coupled to the power source 242 through the platen assembly 230 and are movable to extend at least partially through apertures formed in the processing pad assembly 222. Positions of the contact assemblies 250 may be chosen to have a predetermined configuration across the platen assembly 230. The contact assemblies 250 may be coupled to the platen assembly 230, part of the processing pad assembly 222, or a separate element. In addition, any number of contact assemblies may be utilized and may be distributed in any number of configurations relative to the centerline of the platen assembly 230. One contact assembly that may be adapted to benefit from the invention is described in U.S. patent application Ser. No. 10/445,239, filed May 23, 2003, by Butterfield, et al, and is hereby incorporated by reference in its entirety. For example, the contact assembly 250 may be a rolling ball contact or any structure or assembly having a conductive upper layer or surface suitable for electrically biasing the substrate 122 during processing. Other examples of suitable contact assemblies are described in U.S. Provisional Patent Application Ser. No. 60/516,680, filed Nov. 3, 2003, by Hu, et al, which is hereby incorporated by reference in its entirety.

The power source 242 generally provides a positive electrical bias to the contact assembly 250 during processing. Between planarization processes, the power source 242 may optionally apply a negative bias to the contact assembly 250 to minimize attack on the contact assembly 250 by process chemistries.

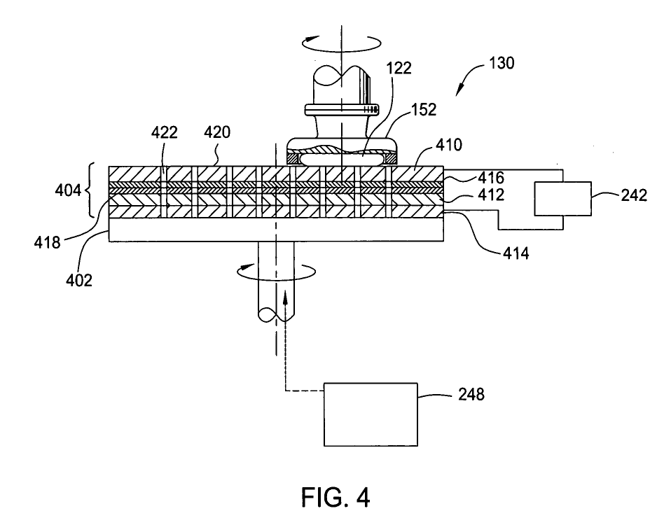

FIG. 4 is a sectional view of another embodiment of an ECMP planarization station that may be adapted to the first, second, or third planarization station. The ECMP planarization station generally includes a platen 402 that supports a fully conductive processing pad assembly 404. The platen 402 may be configured similar to the platen assembly 230 described above to deliver an electrolyte solution through the processing pad assembly 404. Alternatively, the platen 402 may have a fluid delivery arm (not shown) disposed adjacent thereto and configured to supply the electrolyte solution to a planarization surface of the processing pad assembly 404. The platen 402 may also include at least one of a meter or a sensor 254 to facilitate endpoint detection.

The processing pad assembly 404 includes an interposed pad 412 sandwiched between a conductive pad 410 and an electrode 414. The conductive pad 410 is substantially conductive across its top processing surface and is generally made from a conductive material or a conductive composite (i.e., the conductive elements are dispersed integrally with or comprise the material comprising the planarization surface), such as a polymer matrix having conductive particles dispersed therein or a conductive coated fabric, among others. The conductive pad 410, the interposed pad 412, and the electrode 414 may be fabricated into a single, replaceable assembly. The processing pad assembly 404 is generally permeable or perforated to allow electrolyte to pass between the electrode 414 and top surface 420 of the conductive pad 410. In the embodiment depicted in FIG. 4, the processing pad assembly 404 is perforated by one or more apertures 422 to allow electrolyte to flow therethrough. In another embodiment, the conductive pad 410 is comprised of a conductive material disposed on a polymer matrix disposed on a conductive fiber, for example, tin particles in a polymer matrix disposed on a woven copper coated polymer. The conductive pad 410 may also be utilized for the contact assembly 250 in the embodiment of FIG. 3.

A conductive foil 416 may additionally be disposed between the conductive pad 410 and the interposed pad 412. The conductive foil 416 is coupled to a power source 242 and provides uniform distribution of voltage applied by the source 242 across the conductive pad 410. In embodiments not including the conductive foil 416, the conductive pad 410 may be coupled directly, for example, via a terminal integral to the conductive pad 410, to the power source 242. Additionally, the processing pad assembly 404 may include an interposed pad 418, which, along with the conductive foil 416, provides mechanical strength to the conductive pad 410 overlying the conductive foil 416. Examples of suitable processing pad assemblies are described in the previously incorporated U.S. patent applications 10/455,941 and 10/455,895, which are herein incorporated by reference in its entirety.

Referring back to FIG. 2, one or more of the first, second and third planarization stations, 128, 130, 132, can be adapted to include a conventional chemical mechanical (CMP) planarization station having a polishing media, such as a rectangular polishing web or a round polishing surface, disposed between a polishing head assembly and the planarization station. The polishing web may include abrasive sheet polishing media comprised of embedded abrasive particles. The polishing web may have a smooth surface, a textured surface, a surface containing an abrasive in a binder material, or a combination thereof.

Alternatively, polishing media without embedded abrasive particles, such as a polishing pad composed of microporous polyurethane foam, polyurethane foam mixed with filler, polyurethane impregnated felts, or other materials with binders or subpads underneath as backing support, may also be used. The polishing pad or polishing web may include a hard polishing pad, a soft polishing pad, or combinations thereof. A hard polishing pad or a low compressibility pad is broadly described herein as a polishing material having a polishing surface of a hardness of about 50 or greater on the Shore D Hardness scale for polymeric materials as described and measured by the American Society for Testing and Materials (ASTM), headquartered in Philadelphia, Pa. A suitable hard polishing pad is a material comprising the IC-1000, IC-1010, and the IC-1400 polishing pads available from Rodel Inc., of Phoenix Ariz. (IC-1000 is a product name of Rodel, Inc.)

A soft polishing pad or a high compressibility pad is broadly described herein as a polishing material having a polishing surface of a hardness of less than about 50 on the Shore D Hardness scale for polymeric materials as described and measured by ASTM. An example of a soft polishing material is polyurethane impregnated with felt. A soft polishing pad is available as the Politex or Suba series, i.e., Suba IV, available from Rodel, Inc. Politex and Suba are tradenames of Rodel Inc. The invention is equally applicable to all polishing pads having the hardness described herein.

The polishing pad may also include composite pads of one or more layers, with a surface layer having a hardness of about 50 or greater on the Shore D Hardness scale. The composite pads may have an overall hardness of less than about 50 on the Shore D Hardness scale. Alternatively, the polishing pad may be a standard two-layer pad in which the upper layer has a durable roughened surface and is harder than the lower layer. For example, the upper layer of the two-layer pad may be composed of microporous polyurethane or polyurethane mixed with filler, whereas the lower layer maybe composed of compressed felt fibers leached with urethane. A two-layer standard pad, with the upper materials composed of IC-1000 and the lower materials composed of SUBA-4, is available from Rodel, Inc. (IC-1000 and SUBA-4 are product names of Rodel, Inc.).

It is understood that, even though the planarization system 100 as described herein includes three planarization stations, the invention can also be adapted to perform on a polishing system having only one platen or two or more platens.

Polishing Composition and Process

Polishing compositions and processes that can planarize conductive metal materials and barrier material using the planarization system and apparatus of the invention are provided. The invention contemplates the use of various polishing compositions, slurries, polishing electrolytes, etc., in a full sequence electrochemical planarization technique or a hybrid of conventional chemical mechanical planarization and electrochemical planarization process, as described in further detail below.

Most polishing slurries include oxidizers to help oxidize metal materials into their corresponding oxide, hydroxide, or ion states, and remove metal materials from a substrate surface. One problem with peroxide type oxidizers, such as hydrogen peroxide, is that even though hydrogen peroxide help to clear defects, micro scratches, and rough finished surface, a slurry with hydrogen peroxide oxidizer tends to exhibit low removal rate at low down force (thus, low polish pressure) and poor planarization efficiency, for example, a poor dishing performance with dishing of more than 400 Å on features larger than 100 microns.

One embodiment of the invention provides at least two oxidizers to be used in one or more polishing compositions or electrolytes for a full sequence or a hybrid planarization technique. The at least two oxidizers may comprise a first oxidizer, such as a persulfate type oxidizer and the like, and a second oxidizer, such as a peroxide type oxidizer, and the like.

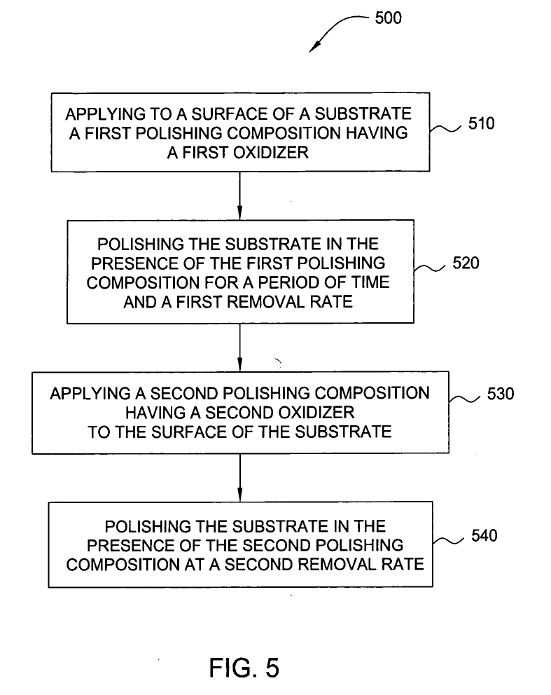

Another embodiment of the invention provides a multi-step polishing process 500 for polishing a substrate surface. As shown in FIG. 5, a first polishing composition is applied to a surface of a substrate at step 510. The first polishing composition include the first oxidizer in order to remove a bulk metal material, a bulk barrier material, and/or any residual materials and expose an underlying material layer using a full sequence or a hybrid planarization technique. The underlying material layer may be a barrier layer and/or a dielectric layer. The exposure of the underlying material layer can be detected by an end point detection module in a planarization system.

Step 520 includes polishing the substrate in the presence of the first polishing composition for a period of desired time and at a first removal rate. The first removal rate can be a high removal rate due to the presence of the first polishing composition having the first oxidizer, such as a removal rate of about 1500 Å/min or higher, such as about 2,000 Å/min or higher, or even about 2,500 Å/min or higher. This high removal rate can be obtained even at low down force, low polishing pressure, e.g., at low polishing pressure of about 1 psi or lower, or about 0.7 psi or lower, and significantly overcome prior art methods of low removal rate at low polishing pressure.

The polishing duration using the first polishing composition may be between about 10 seconds to about 2 minutes or longer, such as about 40 seconds to about 80 seconds, depending on what metal material being polished and its thickness. The first oxidizer in the first polishing composition provides good topography results on a substrate after polishing. The invention contemplates that Step 520 may include additional one or more steps in order to polish the bulk of the metal material and expose the underlying material layer.

The first oxidizer may be a persulfate compound, such as dipersulfate compounds, monopersulfate compounds, e.g., ammonium persulfate, sodium persulfate, potassium persulfate, etc. The first polishing composition may include a concentration of from about 0.2 wt % to about 50 wt % of the first oxidizer, such as a concentration of from about 0.5 wt % to about 6 wt % of the first oxidizer. For example, about 3 wt % of ammonium persulfate used in the first polishing composition for polishing is found to reduce dishing, with a dishing of less than about 200 Å, and effectively polish a copper material. As another example, ammonium persulfate used in the first polishing composition for polishing a barrier material is found to reduce dishing, with a dishing of less than about 50 Å.

Step 530 is then performed to over polish the metal materials on the surface and clear any residual metal or barrier material on the exposed underlying material layer and includes applying a second polishing composition to the surface of the substrate. The substrate is polished in the presence of the second polishing composition at a second removal rate at step 540. The second polishing composition includes the second oxidizer such that any material residues are cleaned from the substrate surface, leaving behind a smooth finished surface with no defects or micro scratches, etc. The polishing duration in the presence of the second polishing composition is not limited, so long as the substrate surface is cleared after a short period of polishing time or as detected by an end point detection technique. For example, the substrate can be over polished for about 5 seconds or longer, such as between about 5 seconds and 20 seconds or longer, in order to clear metal residue and smooth the exposed substrate surface, resulting in no defect formation, while maintaining the topography.

The second oxidizer may be a compound having an element in its highest oxidation state or a peroxy compound that may dissociate into hydroxyl radicals, including, but not limited to, peroxide compounds, percarboxyl acid compounds, permanganates, perboric acids, perbromic acids, and their salts thereof. For example, hydrogen peroxide, peracetic acid, sodium peroxide, perboric acid, sodium percarbonate, perbromate salts, perchloric acid, urea hydrogen peroxide, potassium permanganate, sodium permanganate, urea peroxide, potassium periodate, and salts thereof, among others, can be used as the second oxidizer. In one embodiment, hydrogen peroxide is found to be used in the second polishing composition to reduce defect formation and clean up copper residues exposed on top of a tantalum nitride barrier material. The second polishing composition may include a concentration of from about 0.2 wt % to about 50 wt % of the second oxidizer, such as a concentration of betweeen about 0.5 wt % to about 10 wt % or between about 1 wt % and 6 wt % of the second oxidizer. For example, a second polishing composition having about 3% of hydrogen peroxide is used to reduce micro scratches, resulting in a smooth surface finish.

Other examples of oxidizers and oxidizing agents that can be used in the first and/or second polishing compositions include, without limitation, potassium iodate, and cerium compounds including ceric nitrate, ceric ammonium nitrate, ferric nitrate, nitric acid, and potassium nitrate, bromates, chlorates, chromates, iodic acid, among others. Examples of suitable oxidizer compounds beyond those listed herein are nitrate compounds including ferric nitrate, nitric acid, and potassium nitrate. The oxidizer may be present in an amount between about 0.1 wt% and about 10 wt.%, such as between about 1 wt% and about 5 wt.%, for example about 3 wt.%.

Examples of other suitable oxidizersthat can be adapted to benefit from the invention are described in co-pending co-pending U.S. patent application Ser. No. 10/456,220 (AMAT/5699.P2), titled “Method and Composition for Polishing a Substrate”, filed on Jun. 6, 2003; and U.S. provisional patent application Ser. No. 60/648,128 (AMAT/9824L), filed on Jan. 28, 2005, entitled “Method and Composition for Polishing a Substrate”. Each of the aforementioned related patent applications is herein incorporated by reference.

One embodiment of the invention provide that the second polishing composition may be the same polishing composition as the first polishing composition having the same chemical components except that the first oxidizer is replaced by the second oxidizer. Alternatively, the second polishing composition may have a different chemical make up than the first polishing composition. In another embodiment, the second polishing composition may include both the first oxidizer and the second oxidizer to overpolish the metal material and smooth the substrate surface. In still another embodiment, the second polishing composition can be used to clean or buff any remaining conductive metal material or barrier material on a substrate surface.

The first polishing composition and the second polishing composition can be used alone or in combination, sequentially or separately in a full sequence or a hybrid planarization technique. One aspect or component of the present invention is the use of one or more oxidizer or oxidizing agents to complex with the surface of the substrate to enhance the polishing and/or electrochemical dissolution process. In any of the embodiments described herein, the oxidizers can bind to ions of a conductive material, such as tungsten or copper, increase the removal rate of metal materials and/or improve polishing performance.

This application is related to co-pending U.S. patent application Ser. No. 10/941,060 (AMAT/9281), entitled “Full Sequence Metal and Barrier Layer Electrochemical Mechanical Processing”, filed on Sep. 14, 2004; co-pending U.S. patent application Ser. No. 10/456,220 (AMAT/5699.P2), titled “Method and Composition for Polishing a Substrate”, filed on Jun. 6, 2003; and U.S. provisional patent application Ser. No. 60/648,128 (AMAT/9824L), filed on Jan. 28, 2005, entitled “Method and Composition for Polishing a Substrate”. Each of the aforementioned related patent applications is herein incorporated by reference.

Polishing Technique

One aspect of the invention as described herein provides a full sequence electrochemical mechanical polishing technique using a combination of chemical activity, mechanical activity and electrical activity to remove metal materials and planarize a substrate surface. The full sequence electrochemical mechanical polishing technique may include polishing a bulk portion of a metal layer deposited on a substrate surface on an ECMP planarization station and polishing a second portion or residual portion of the metal layer on the same or another ECMP planarization station to planarize the metal layer on the substrate surface. Polishing the second portion of the metal layer may be a clearing step to clear any remaining metal material to expose an underlying barrier layer. Thereafter, the barrier layer underlying the metal layer on the substrate surface may be planarized on the same or a different ECMP station.

Bulk portion or bulk material is broadly defined herein as any material deposited on the substrate in an amount more than sufficient to substantially fill features formed on the substrate surface. Residual portion or residual material is broadly defined as any material remaining after one or more bulk or residual polishing process steps. Generally, bulk material removal may remove at least about 50% of the conductive layer, such as at least about 70%, e.g., at least about 90%. The residual removal may remove most of, if not all, the remaining metal material to leave behind a planarized substrate surface and metal-filled features.

In another aspect, a hybrid polishing technique using a combination of ECMP and CMP polishing techniques to remove metal materials and planarize a substrate surface can be performed as described herein. The hybrid polishing technique can be performed in a planarization system having one or more ECMP planarization station and one or more CMP planarization station, such as the planarization system 100 of the invention.

For example, the apparatus described above in accordance with the processes described herein may include three platens or planarization stations for removing a metal material layer including, for example, a first planarization station to remove bulk material, a second planarization station for residual removal and a third planarization station for barrier removal, wherein the bulk and the residual processes are ECMP processes and the barrier removal is a CMP process. In an alternative embodiment, the bulk material is removed by a CMP process and an ECMP process may be used to remove the residual metal material, wherein the barrier material is removed by an ECMP or CMP process.

In another embodiment, the removal of a metal layer is performed in one or more processing steps, for example, a single metal removal step to planarize a substrate surface, or a bulk metal removal step and a residual metal removal step. In addition, two or more steps can be performed in the same planarization station.

In operation, an electrochemical mechanical polishing technique (ECMP) includes disposing a substrate in a receptacle, such as a basin, platen, or planarization station containing a contact or a first electrode, such as the contact assembly 250. The planarization station further includes a conductive polishing pad coupled to a processing pad assembly containing a second electrode, such as a processing pad assembly 222 having the electrode 292 therein. The electrodes, contact assembly, and processing pad assembly are provided to contact the substrate and powered to be electrically coupled with the substrate. The substrate may have a dielectric layer patterned with narrow feature definitions and wide feature definitions. In addition, the substrate may have a barrier material deposited therein followed by filling of a conductive metal material. Then, a polishing composition or an ECMP electrolyte as described below is provided to the substrate surface. The polishing composition may be provided at a flow rate between about 100 ml/min and about 400 ml/min, such as about 300 ml/min, to the substrate surface.

The substrate retained in the carrier head is lowered to be in contact with the contact assembly 250 and the processing pad assembly 222. A bias from a power source 242 is applied between the two electrodes to electrically couple the substrate. The bias may be transferred from a conductive pad and/or electrode in the polishing article assembly 222 to the substrate 208. The bias is generally provided at a current density up to about 100 mA/cm² which correlates to an applied current of about 40 amps to process substrates with a diameter up to about 300 mm. For example, a 200 mm diameter substrate may have a current density from about 0.01 mA/cm² to about 50 mA/cm², which correlates to an applied current from about 0.01 A to about 20 A. The invention also contemplates that the bias may be applied and monitored by volts, amps and watts. For example, in one embodiment, the power supply may apply a power between about 0 watts and 100 watts, a voltage between about 0 V and about 10 V, and a current between about 0.01 amps and about 10 amps. In one example of power application a voltage of between about 2.5 volts and about 4.5, such as about 3 volts, volts is applied during application of the bulk polishing composition described herein to the substrate.

The substrate is typically exposed to the polishing composition and power application for a period of time sufficient to remove the bulk of the overburden of tungsten, for example, disposed thereon. The process may be performed at a temperature between about 0° C. and about 60° C.

The substrate is typically exposed to the polishing composition and power application for a period of time sufficient to planarize the substrate surface which is generally monitored by an end point detection module in the planarization system. The bias may also be applied by an electrical pulse modulation technique. Pulse modulation techniques may vary, but generally include a cycle of applying a constant current density or voltage for a first time period, then applying no current density or voltage or a constant reverse current density or voltage for a second time period. The process may then be repeated for one or more cycles, which may have varying power levels and durations.

One example of a pulse modulation process is described in commonly assigned U.S. Pat. No. 6,379,223, which is incorporated by reference herein to the extent not inconsistent with the claimed aspects and disclosure herein. Further examples of a pulse modulation process is described in co-pending U.S. Provisional patent application Ser. No. 10/611,805, entitled “Effective Method To Improve Surface Finish In Electrochemically Assisted Chemical Mechanical Polishing,” filed on Jun. 30, 2003, which is incorporated by reference herein to the extent not inconsistent with the claimed aspects and disclosure herein.

The power levels, the duration of power, and frequency of cycles, may be modified based on the removal rate, materials to be removed, and the extent of the polishing process. For example, increased power levels and increased duration of power being applied have been observed to increase anodic dissolution. The cycles may be repeated as often as desired for each selected process.

The substrate surface and the polishing pad are contacted at a pressure less than about 2 pounds per square inch (lb/in² or psi) (13.8 kPa). Removal of the conductive metal material may be performed at a pressure of about 1 psi (6.9 kPa) or less, for example, from about 0.01 psi (69 Pa) to about 1 psi (6.9 kPa), such as between about 0.1 (0.7 kPa) psi and about 0.8 psi (5.5 kPa) or between about 0.1 (0.7 kPa) psi and less than about 0.5 psi (3.4 kPa). In one aspect of the process, a pressure of about 0.3 psi (2.1 kPa) or less is used. The polishing pressures used herein reduce or minimize damaging shear forces and frictional forces applied on a substrate, such as substrates containing low k dielectric materials. Reduced or minimized forces can result in reduced or minimal deformations and defect formation of features from polishing. Further, the lower shear forces and frictional forces have been observed to reduce or minimize formation of topographical defects, such as erosion of dielectric materials and dishing of conductive materials as well as reducing delamination, during polishing.

Relative motion is provided between the substrate surface and the processing pad assembly 222. For example, the processing pad assembly 222 disposed on the planarization station is rotated at a platen rotational rate of between about 7 rpm and about 50 rpm, for example, about 28 rpm, and the substrate disposed in a carrier head is rotated at a carrier head rotational rate between about 7 rpm and about 70 rpm, for example, about 37 rpm. The respective rotational rates of the planarization station and carrier head are believed to provide reduced shear forces and frictional forces when contacting the polishing article and substrate. Both the carrier head rotational speed and the platen rotational speed may be between about 7 rpm and less than 40 rpm.

A removal rate of conductive material of up to about 15,000 Å/min can be achieved by the processes described herein. Higher removal rates are generally desirable, but due to the goal of maximizing process uniformity and other process variables (e.g., reaction kinetics at the anode and cathode) it is common for dissolution rates to be controlled from about 100 Å/min to about 15,000 Å/min.

In one embodiment of the invention where the bulk tungsten material to be removed is less than 5,000 Å thick, the voltage (or current) may be applied to provide a removal rate from about 100 Å/min to about 5,000 Å/min, such as between about 2,000 Å/min to about 5,000 Å/min, by a conventional CMP or an ECMP process. The residual material is removed at a rate lower than the bulk removal rate and by an ECMP process described herein at a rate between about 400 Å/min to about 1,500 Å/min. The second ECMP process is slower in order to prevent excess metal removal from forming topographical defects, such as concavities or depressions known as dishing and erosion. In one embodiment, a first polishing pressure in the first polish process is higher than the second polishing pressure in the second ECMP process in order to increase the first removal rate and throughput without damaging the substrate surface. Therefore, a majority of the tungsten material is removed at a faster removal rate during the first process than the remaining or residual tungsten material during the second ECMP process. The two-step process increases throughput of the total substrate processing and while producing a smooth surface with little or no defects. In a further embodiment, endpoint of the first polish process and the second ECMP polish process can be detected and determined by an end point detection module connected to the polishing system.

In another embodiment of the invention where the bulk copper material to be removed is about 10,000 Å thick, the voltage (or current) may be applied to provide a removal rate from about 100 Å/min to about 10,000 Å/min, such as between about 200 Å/min to about 10,000 Å/min, by an ECMP process or a conventional CMP process. The residual material is removed at a rate lower than the bulk removal rate and by a second ECMP or a second CMP process at a rate between about 200 Å/min to about 3,000 Å/min. The ECMP process at low polish pressure prevent damage to low k material typically underlying the copper material layer on the substrate surface and provide control over dishing and erosion problems.

Polishing compositions of the invention may also include abrasive particles, such as inorganic abrasives, polymeric abrasives, and combinations thereof. Suitable abrasives particles that may be used in the electrolytes and/or polishing compositions include, but are not limited to, silicon, silica, colloidal silica, silicon oxide, cerium, ceria, ceria oxide, aluminum, alumina oxide, alumina, titanium, titania oxide, zirconia, zirconium oxide, germanium, germania oxide, any other abrasives of metal oxides, and combinations thereof, among others. The concentration of the abrasives in the polishing composition, slurries, and/or electrolytes of the invention can vary, depending on the material to be polished. For example, a concentration of between about 0.2% and about 20%, such as between about 0.5% to about 3% can be used. When an ECMP process is performed, the polishing composition/electrolyte used may include little or no abrasive.

Suitable oxidizers and abrasives are described in co-pending U.S. patent application Ser. No. 10/378,097, filed on Feb. 26, 2004, which is incorporated by reference herein to the extent not inconsistent with the claimed aspects and disclosure herein. Abrasives particles may be used to improve the surface finish and removal rate of conductive metal and/or barrier materials from the substrate surface during polishing. The addition of abrasive particles to the polishing compositions can allow the final polished surface to achieve a surface roughness of that comparable with a conventional CMP process even at low pad pressures. Surface finish has been shown to have an effect on device yield and post polishing surface defects. Abrasive particles may comprise about 0.2 wt % or more of the polishing compositions during processing. A concentration between about 0.3 wt % and about 10 wt %, for example about 4 wt % of abrasive particles may be used as a barrier metal polishing composition.

The typical abrasive particle size used is generally from about 1 nm to about 1,000 nm, such as between about 30 nm and about 500 nm, for example, between about 30 nm and about 200 nm. Generally, suitable inorganic abrasives have a Mohs hardness of greater than 6, although the invention contemplates the use of abrasives having a lower Mohs hardness value. The polymer abrasives described herein may also be referred to as “organic polymer particle abrasives”, “organic abrasives” or “organic particles.” The polymeric abrasives may comprise abrasive polymeric materials. Examples of polymeric abrasives materials include polymethylmethacrylate, polymethyl acrylate, polystyrene, polymethacrylonitrile, and combinations thereof. The polymeric abrasives may be modified to have functional groups, e.g., one or more functional groups, that have an affinity for, i.e., can bind to, the conductive material or conductive material ions at the surface of the substrate, thereby facilitating the removal of material from the surface of a substrate.

Other additives may be optionally included in the polishing compositions of the invention. One class of such additives is inorganic acids and salts thereof, which can be added to the first and/or second polishing compositions to further enhance metal removal from a substrate surface. Useful inorganics include, but are not limited to, sulfuric acid, phosphoric acid, phosphonic acid, nitric acid, fluoric aicd, ammonium salts, potassium salts, sodium salts, phosphates salts, phosphonate salts, sulfate salts, among others.

Other additives or chelating agents which can be optionally added to the polishing compositions includes organic acid and/or their salts, such as salts of compounds having one or more functional groups selected from the group of carboxylate groups, dicarboxylate groups, tricarboxylate groups, a mixture of hydroxyl and carboxylate groups, and combinations thereof. The functional groups can bind the metal materials created on the substrate surface during processing and remove the metal materials from the substrate surface. The polishing compositions may include one or more inorganic or organic salts at a concentration between about 0.1% and about 15% by volume or weight of the composition, for example, between about 0.2% and about 5% by volume or weight, such as between about 1% and about 3% by volume or weight. For example, between about 0.5% and about 2% by weight of ammonium citrate may be used in the polishing composition.

Examples of suitable inorganic or organic acid salts include ammonium and potassium salts of organic acids, such as ammonium oxalate, ammonium citrate, ammonium succinate, monobasic potassium citrate, dibasic potassium citrate, tribasic potassium citrate, potassium tartarate, ammonium tartarate, potassium succinate, potassium oxalate, and combinations thereof. Examples of suitable acids for use in forming the salts of the chelating agent that having one or more carboxylate groups include citric acid, tartaric acid, succinic acid, oxalic acid, acetic acid, adipic acid, butyric acid, capric acid, caproic acid, caprylic acid, glutaric acid, glycolic acid, formaic acid, fumaric acid, lactic acid, lauric acid, malic acid, maleic acid, malonic acid, myristic acid, plamitic acid, phthalic acid, propionic acid, pyruvic acid, stearic acid, valeric acid, and combinations thereof.

Alternatively, a second chelating agent having one or more functional groups selected from the group of amine groups, amide groups, hydroxyl groups, and combinations thereof, may be used in the composition, at a concentration between about 0.1% and about 5% by volume or weight, such as between about 1% and about 3% by volume or weight, for example about 2% by volume or weight. For example, between about 2 vol % and about 3 vol % of ethylenediamine, diethylenetriamine, amino acids, ethylenediaminetetraacetic acid, methylformamide, or hexadiamine may be used as a chelating agent.

The pH of the polishing composition as described herein is not limiting and can be, for example, a pH of about 7 or greater. However, some slurries may be used at a acidic pH. The polishing compositions of the invention may include one or more pH adjusting agents to achieve a pH between about 7 and about 12. The amount of pH adjusting agent can vary as the concentration of the other components is varied in different formulations, but in general the total solution may include up to about 70 wt % of the one or more pH adjusting agents, but preferably between about 0.2 wt % and about 25 wt. %. The composition may include between about 0.1 wt % and about 10 wt % of a base, such as potassium hydroxide, sodium hydroxide, ammonium hydroxide, tetramethyl ammonium hydroxide (TMAH), or combinations thereof, to provide the desired pH level. The one or more pH adjusting agents can be chosen from a class of organic acids, for example, carboxylic acids, such as acetic acid, citric acid, oxalic acid, phosphate-containing components including phosphoric acid, ammonium phosphates, potassium phosphates, and combinations thereof. Inorganic acids including hydrochloric acid, sulfuric acid, and phosphoric acid may also be used in the polishing compositions.

Typically, the amount of pH adjusting agents in the polishing composition will vary depending on the desired pH range for components having different constituents for various polishing processes. For example, in a bulk tungsten polishing process, the amount of pH adjusting agents may be adjusted to produce pH levels between about 6 and about 10. In one embodiment of the bulk tungsten removal composition, the pH is a neutral or basic pH in the range between about 7 and about 9, for example, a basic solution greater than 7 and less than or equal to about 9, such as between about 8 and about 9. In another embodiment, a polishing solution for bulk copper may have an acidic pH of between about 1 and about 7, such as between about 3 and about 6, for example between about 4 and about 5.

In any of the embodiments described herein, etching inhibitors, stabilizers, for example, corrosion inhibitors, polymeric stabilizers, can be added to reduce the oxidation or corrosion of metal surfaces, by chemical or electrical means, by forming a layer of material which minimizes the chemical interaction between the substrate surface and the surrounding electrolyte. The layer of material formed by the inhibitors may suppress or minimize the electrochemical current from the substrate surface to limit electrochemical deposition and/or dissolution.

Etching inhibitors of copper inhibits the conversion of solid copper into soluble copper compounds while at the same time allowing the composition to convert tungsten to a soft oxidized film that can be evenly removed by abrasion. Useful etching inhibitors include compounds having nitrogen containing functional groups such as nitrogen containing heteroycles, alkyl ammonium ions, amino alkyls, amino acids. Etching inhibitors include corrosion inhibitors, such as compounds including nitrogen containing heterocycle functional groups, for example, 2,3,5-trimethylpyrazine, 2-ethyl-3,5-dimethylpyrazine, quinoxaline, acetyl pyrrole, pyridazine, histidine, pyrazine, benzimidazole and mixtures thereof.

The first and second polishing compositions may include one or more surface finish enhancing and/or removal rate enhancing materials. For example, one or more surfactants can be used increase the dissolution or solubility of materials, such as metals and metal ions or by-products produced during processing, reduce any potential agglomeration of abrasive particles in the polishing composition, improve chemical stability, and reduce decomposition of components of the polishing composition.

Alternatively, the polishing composition may further include electrolyte additives including suppressors, enhancers, levelers, brighteners, stabilizers, and stripping agents to improve the effectiveness of the polishing composition in polishing of the substrate surface. For example, certain additives may decrease the ionization rate of the metal atoms, thereby inhibiting the dissolution process, whereas other additives may provide a finished, shiny substrate surface. The additives may be present in the polishing composition in concentrations up to about 15% by weight or volume, and may vary based upon the desired result after polishing. Further examples of additives to the polishing composition are more fully described in U.S. patent application Ser. No. 10/141,459, filed on May 7, 2002, which is incorporated by reference herein to the extent not inconsistent with the claimed aspects and disclosure herein.

The balance or remainder of the polishing compositions described above is a solvent, such as a polar solvent, including water, preferably deionized water. Other solvents may include, for example, organic solvents, such as alcohols or glycols, and in some embodiments may be combined with water. The amount of solvent may be used to control the concentrations of the various components in the composition. For example, the electrolyte may be concentrated up to three times as concentrated as described herein and then diluted with the solvent prior to use of diluted at the processing station as described herein.

The polishing compositions of the invention may have a conductivity of between about 60 and about 64 milliSiemens (mS) to be used as an electrolyte for an electrochemical mechanical (ECMP) process. Generally, ECMP solutions are much more conductive than traditional CMP solutions. The ECMP solutions have a conductivity of about 10 milliSiemens (mS) or higher, while traditional CMP solutions have a conductivity from about 3 mS to about 5 mS. The conductivity of the ECMP solutions greatly influences the rate at which the ECMP process advances, i.e., more conductive solutions have a faster material removal rate. For removing bulk material, the ECMP solution has a conductivity of about 10 mS or higher, preferably in a range between about 40 mS and about 80 mS, for example, between about 50 mS and about 70 mS, such as between about 60 and about 64 mS. For residual material, the ECMP solution has a conductivity of about 10 mS or higher, preferably in a range between about 30 mS and about 60 mS, for example, between about 40 mS and about 55 mS, such as about 49 mS.

After conductive material and barrier material removal processing steps, the substrate may then be buffed to minimize surface defects. Buffing may be performed in the planarization system 100 using a soft polishing article and/or at reduced polishing pressures, such as about 2 psi or less. Optionally, a cleaning solution may be applied to the substrate after each of the polishing processes/steps to remove particulate matter and spent reagents from the polishing process as well as help minimize metal residue deposition on the polishing pads/articles and defects formed on a substrate surface. One example of a suitable cleaning solution is ELECTRA CLEAN™ solution, commercially available from Applied Materials, Inc., of Santa Clara, Calif.

In addition, the substrate may be exposed to a post polishing cleaning process to reduce defects formed during polishing or substrate handling. Such processes can minimize undesired oxidation or other defects in copper features formed on a substrate surface. An example of such a post polishing cleaning is the application of ELECTRA CLEAN™ solution, commercially available from Applied Materials, Inc., of Santa Clara, Calif.

It has been observed that substrate planarized by the processes and polishing composition described herein have exhibited reduced topographical defects, such as dishing and erosion, reduced residues, less surface defects and scratches, improved planarity, and improved substrate finish. The invention also contemplates that conventional electrolytes or slurries known and unknown may also be modified with oxidizers of the invention and used in forming the first and second polishing compositions described herein and using the processes/planarization techniques described herein.

The following non-limiting examples are provided to further illustrate embodiments of the invention. However, the examples are not intended to be all inclusive and are not intended to limit the scope of the inventions described herein.

### EXAMPLES

Slurries A, B, C, and D were initially prepared in a multi-step polishing process for polishing bulk conductive metal or barrier material in a first step and residual conductive metal or barrier materials in a second step. The oxidizer used in Slurry A is hydrogen peroxide and the oxidizer used in Slurry B is ammonium persulfate. Slurry C includes the same Slurry B make up but hydrogen peroxide is used to replace ammonium persulfate as the oxidizer. Slurry D includes the same Slurry B make up but hydrogen peroxide is added together with ammonium persulfate as the oxidizers. Three Examples, I, II, and III, respectively, were tested in the two step polishing process.

Example I includes Slurry B in the first step and Slurry A in the second step. Example II includes Slurry B (ammonium persulfate as the first oxidizer) in the first step and Slurry C (hydrogen peroxide as the second oxidizer) in the second step. Example III includes Slurry B in the first step and Slurry D in the second step. Slurry D in the second step includes two oxidizers, ammonium persulfate and hydrogen peroxide.

A copper plated substrate of 300 mm diameter was polished and planarized using the above polishing compositions within a modified cell on a REFLEXION® system, available from Applied Materials, Inc., of Santa Clara, Calif. A substrate having a copper layer of about 10,000 Å thick on the substrate surface was placed onto a carrier head in an apparatus having a first platen with a first polishing article disposed thereon. A first polishing composition was supplied to the platen at a slurry delivery rate of about 250 ml/min in the first step. The substrate was contacted with the first polishing article at a first contact pressure of about 0.5 psi, a first platen rotational rate of about 20 rpm, a first carrier head rotational rate of about 39 rpm and a first bias of about 2.9 volts was applied during the process. The substrate was polished and examined.

The substrate was transferred to over a second platen having a second polishing article disposed thereon. A second polishing composition was supplied to the platen at a slurry delivery rate of about 300 ml/min in the second step. The substrate was contacted with the second polishing article at a second contact pressure of about 0.5 psi, a second platen rotational rate of about 14 rpm, a second carrier head rotational rate of about 29 rpm and a second bias of about 2.4 volts was applied during the process. The substrate was polished and examined. The excess metal material formerly on the substrate surface was removed.

Polish performance using Example I, II, and III in the two step process is illustrated below.

| | | | Erosion | | |
|---|---|---|---|---|---|
| | | | before | Metal | |
| | | | barrier | residue | |
| Slurry | Removal Rate | Dishing (Å) | removed | remained | Metal Surface |
| A alone | 1000 Å/min | 600-700 Å | 400-500 Å | No | Good |
| B alone | 2500 Å/min | <200 Å | <200 Å | 100 Å | Rough |
| Example I | | <300 Å | <300 Å | No | Good |
| Example II | | <300 Å | <300 Å | No | Good |
| Example III | | <300 Å | <300 Å | No | Good |

While the foregoing is directed to embodiments of the present invention, other and further embodiments of the invention may be devised without departing from the basic scope thereof, and the scope thereof is determined by the claims that follow.

1. A method for removing at least a metal material from a surface of the substrate, comprising:
disposing the substrate on a planarization station;
applying a first polishing composition having a persulfate oxidizer to the surface of the substrate to remove at least a portion of the metal material;
polishing the substrate at a first removal rate;
applying a second polishing composition having a peroxide oxidizer to the surface of the substrate to remove a residual portion of the metal material; and
polishing the substrate at a second removal rate.

2. The method of claim 1, wherein the persulfate oxidizer comprises a compound selected form the group consisting of ammonium persulfate, sodium persulfate, potassium persulfate, and combinations thereof.

3. The method of claim 1, wherein the peroxide oxidizer comprises a compound selected form the group consisting of hydrogen peroxide, sodium peroxide, perboric acid, percarbonate, urea peroxide, urea hydrogen peroxide, and combinations thereof.

4. The method of claim 1, wherein the second polishing composition further comprises a persulfate oxidizer.

5. The method of claim 1, wherein the planarization station is a planarization platen selected from the group consisting of a chemical mechanical planarization station, an electrochemical mechanical planarization station, and combination thereof.

6. The method of claim 1, wherein the first polishing composition comprises ammonium persulfate and the second polishing composition comprises hydrogen peroxide.

7. The method of claim 1, wherein, and the metal material comprises a material selected from the group consisting of copper, tungsten, tantalum, tantalum nitride, titanium, titanium nitride, aluminum, ruthenium, their metal alloys, and combinations thereof.

8. A method for removing at least a metal material from a surface of the substrate, comprising:
disposing the substrate on an electrochemical mechanical planarization station; and
polishing the substrate by a full sequence planarization technique, comprising:
applying a first polishing composition having a first oxidizer to the surface of the substrate to remove at least a portion of the metal material;
polishing the substrate at a first removal rate;
applying a second polishing composition having a second oxidizer comprising a peroxide oxidizer to the surface of the substrate to remove a residual portion of the metal material; and
polishing the substrate at a second removal rate.

9. The method of claim 8, wherein the full sequence planarization technique further comprises transferring the substrate to a second electrochemical mechanical planarization station.

10. The method of claim 8, wherein the first polishing composition comprises a persulfate oxidizer.

11. The method of claim 10, wherein the first polishing composition comprises ammonium persulfate and the second polishing composition comprises hydrogen peroxide.

12. The method of claim 10, wherein the second polishing composition further comprises a persulfate oxidizer.

13. The method of claim 10, wherein the metal material comprises a material selected from the group consisting of copper, tungsten, tantalum, tantalum nitride, titanium, titanium nitride, aluminum, ruthenium, their metal alloys, and combinations thereof.

14. A method for removing at least a metal material from a surface of the substrate, comprising:
polishing the substrate by a hybrid planarization technique, comprising:
disposing the substrate on a first planarization station;
applying a first polishing composition having a first oxidizer comprising a persulfate oxidizer to the surface of the substrate to remove at least a portion of the metal material;
polishing the substrate at a first removal rate;
transferring the substrate to a second planarization station;
applying a second polishing composition having a second oxidizer to the surface of the substrate to remove a residual portion of the metal material; and
polishing the substrate at a second removal rate.

15. The method of claim 14, wherein the first planarization station is a planarization platen selected from the group consisting of a chemical mechanical planarization station and an electrochemical mechanical planarization station.

16. The method of claim 14, wherein the second planarization station is a planarization platen selected from the group consisting of a chemical mechanical planarization station and an electrochemical mechanical planarization station.

17. The method of claim 14, wherein the first planarization station is a chemical mechanical planarization station, the second planarization station is an electrochemical mechanical planarization station, and the metal material comprises tungsten.

18. The method of claim 14, wherein the first planarization station is an electrochemical mechanical planarization station, the second planarization station is a chemical mechanical planarization station, and the metal material comprises copper.

19. The method of claim 14, wherein the second polishing composition comprises a oxidizer selected from the group consisting of a persulfate oxidizer, a peroxide oxidizer, and combinations thereof.

20. The method of claim 14, wherein, and the metal material comprises a material selected from the group consisting of copper, tungsten, tantalum, tantalum nitride, titanium, titanium nitride, aluminum, ruthenium, their metal alloys, and combinations thereof.

21. A method for removing at least a metal material from a surface of the substrate, comprising:
polishing the substrate by a hybrid planarization technique, comprising:
disposing the substrate on a chemical mechanical planarization station;
applying a first polishing composition to the surface of the substrate to remove at least a portion of the metal material;
polishing the substrate at a first polishing pressure and first removal rate until a first end point is detected by an end point detection module connected to the chemical mechanical planarization station;
transferring the substrate to an electrochemical mechanical planarization station;
applying a second polishing composition to the surface of the substrate to remove a residual portion of the metal material; and
polishing the substrate at a second polishing pressure and a second removal rate until the surface of the substrate is planarized.

22. The method of claim 21, wherein the first polishing composition comprises a persulfate oxidizer and the second polishing composition comprises a peroxide oxidizer.

23. The method of claim 21, wherein the metal material comprises a material selected from the group consisting of copper, tungsten, tantalum, tantalum nitride, titanium, titanium nitride, aluminum, ruthenium, their metal alloys, and combinations thereof.

24. The method of claim 23, wherein the metal material comprises tungsten.

25. The method of claim 21, wherein the first polishing pressure is higher than the second polishing pressure.

26. A method for removing at least a metal material from a surface of the substrate, comprising:
disposing the substrate on a planarization station;
applying a first polishing composition comprising ammonium persulfate to the surface of the substrate to remove at least a portion of the metal material;
polishing the substrate at a first removal rate;
applying a second polishing composition comprising hydrogen peroxide to the surface of the substrate to remove a residual portion of the metal material; and
polishing the substrate at a second removal rate.

27. The method of claim 26, wherein the planarization station is a planarization platen selected from the group consisting of a chemical mechanical planarization station, an electrochemical mechanical planarization station, and combination thereof.

28. The method of claim 26, wherein the first removal rate is about 1,500 Å/min or higher.

29. The method of claim 26, wherein polishing the substrate at a first removal rate further comprises a first polishing pressure of about 1 psi or lower.
